(19) United States
(12) Patent Application Publication
(10) Pub. No.: US 2026/0314288 A1
(43) Pub. Date: Oct. 8, 2026

(54) DIE EDGE STRUCTURE FOR MOLDING COMPOUND FILLING AND THE METHODS OF FORMING THE SAME

(71) Applicant: Taiwan Semiconductor Manufacturing Co., Ltd., Hsinchu (TW)

(72) Inventors: Min-Hsuan Hsu, Hsinchu (TW); Ting Hao Kuo, Hsinchu (TW); Chih-Sheng Li, Hsinchu (TW); Yu-Chia Lai, Zhunan Township (TW); Chen-Shien Chen, Zhubei City (TW)

(21) Appl. No.: 19/713,956

(22) Filed: Jun. 19, 2026

Related U.S. Application Data
(63) Continuation of application No. 18/657,170, filed on May 7, 2024.
(60) Provisional application No. 63/624,527, filed on Jan. 24, 2024.

(51) Int. Cl. H10P 54/00; H10W 74/01; H10W 74/10

(52) U.S. Cl. CPC H10P 54/00; H10W 74/01; H10W 74/114

(57) ABSTRACT

A method includes forming a wafer, and etching a first dielectric layer of the wafer to form a first trench between two dies of the wafer. A first portion of a second dielectric layer of the wafer is directly underlying the first trench. A laser grooving process is then performed to remove the first portion of the second dielectric layer of the wafer and to form a second trench, which is underlying and joined to the first trench. The second dielectric layer includes a corner region where the first trench is joined to the second trench. Portions of a top surface of the corner region closer to a center middle line of the second trench are increasing lower than respective portions of the top surface of the corner region farther away from the center middle line.

### PRIORITY CLAIM AND CROSS-REFERENCE

This application is a continuation of U.S. application Ser. No. 18/657,170, filed May 7, 2024, and entitled “DIE EDGE STRUCTURE FOR MOLDING COMPOUND FILLING AND THE METHODS OF FORMING THE SAME,” which claims the benefit of U.S. Provisional Application No. 63/624,527, filed on Jan. 24, 2024, and entitled “STRUCTURE FOR MC FILL ENHANCEMENT IN SoIC AND 3DIC,” which applications are hereby incorporated herein by reference.

### BACKGROUND

The packages of integrated circuits are becoming increasing complex, with more device dies integrated in the same package to achieve more functions. For example, packages may be formed to include a plurality of device dies such as processors and memory cubes in the same package. The packages can include device dies formed using different technologies and have different functions bonded to the same device die, thus forming a system. This may save manufacturing cost and achieve optimized device performance.

In a package, a die may be bonded to a package component die through bonding. The die is a part of a wafer, which is sawed into a plurality of identical dies. The bonding of the die to the package component may be performed through one of a plurality of bond schemes such as solder bonding, direct metal-to-metal bonding, hybrid bonding (including both of dielectric-to-dielectric bonding and metal-to-metal bonding), or the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B and 6 illustrate the cross-sectional views of intermediate stages in the dicing of a wafer and the packaging of dies in accordance with some embodiments.

FIG. 7 illustrates a magnified view of a corner portion of a die in accordance with some embodiments.

FIG. 8 illustrates a plane view of the roughness of a corner portion of a die in accordance with some embodiments.

FIGS. 9-17 illustrate the magnified views of corner portions of dies in accordance with some embodiments.

FIG. 18 illustrates a top view of a wafer in accordance with some embodiments.

FIGS. 19-22 illustrate the counts of laser pulses as functions of positions of the laser grooved portions in accordance with some embodiments.

FIG. 23 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A wafer dicing process, the respective dies, and the packaging process are provided. In accordance with some embodiments of the present disclosure, the wafer dicing process includes an etching process to etch the scribe line regions of a wafer. A laser grooving process is performed on the etched portion of the wafer. The laser grooving process is controlled to form gradually changed corners. The laser grooving process may be performed through laser pulses with a low power, so that the roughness of the corner portions may be reduced. With the corner portions of the dies having gradually changed corner portions with small roughness, the dies may be encapsulated in molding compound without causing voids.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

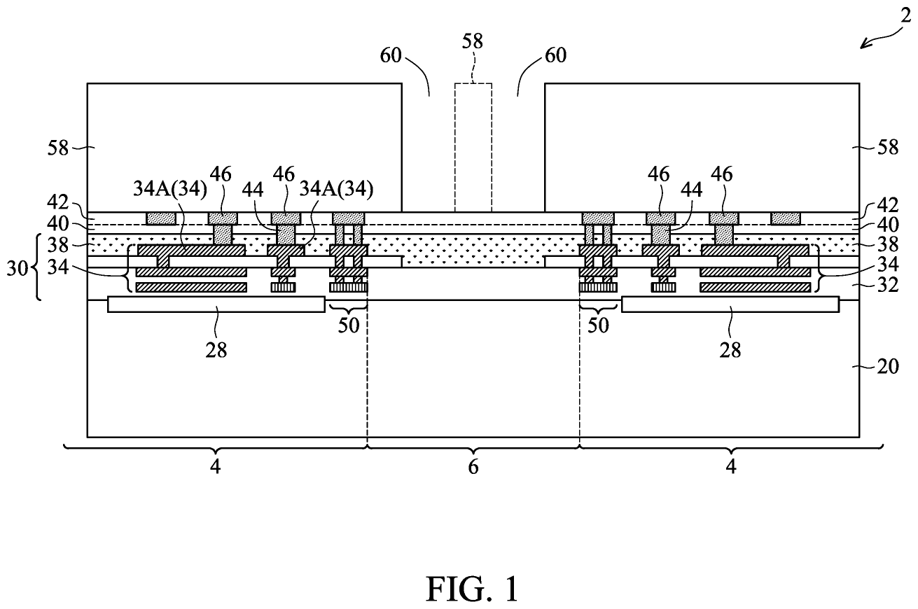

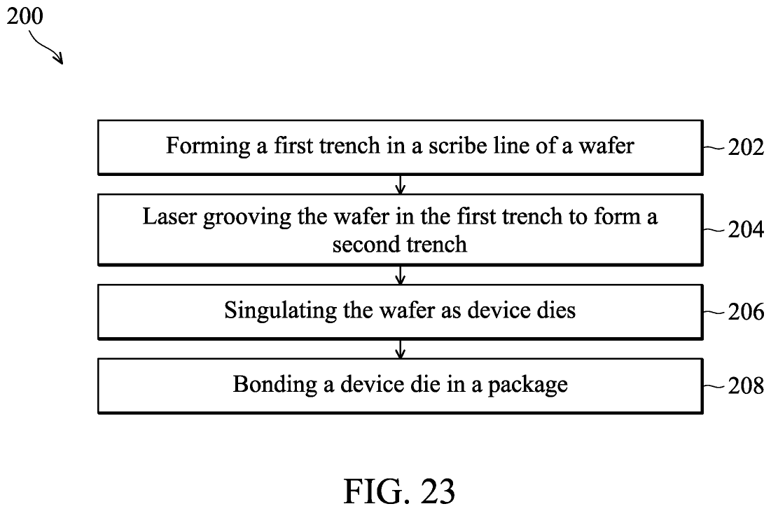

FIGS. 1 through 6 illustrate the cross-sectional views of intermediate stages in the wafer dicing process, the respective dies, and formation of a package using the dies in accordance with some embodiments of the present disclosure. The corresponding processes are also reflected schematically in the process flow 200 as shown in FIG. 23.

FIG. 1 illustrates a cross-sectional view of package component 2. In accordance with some embodiments, package component 2 is a device wafer including active devices such as transistors and/or diodes, and possibly passive devices such as capacitors, inductors, resistors, or the like. Package component 2 may include a plurality of device dies 4 therein, with the edge portions of two device dies 4 being illustrated. Device dies 4 are alternatively referred to as chips hereinafter. In accordance with some embodiments, device die 4 is a memory die such as a Dynamic Random-Access Memory (DRAM) die or a Static Random-Access Memory (SRAM) die. Device die 4 may also be a logic die, which may be a Central Processing Unit (CPU) die, a Micro Control Unit (MCU) die, an input-output (IO) die, a BaseBand (BB) die, an Application processor (AP) die, or the like.

In accordance with some embodiments, wafer 2 includes semiconductor substrate 20 and the features formed at a top surface of semiconductor substrate 20. Semiconductor substrate 20 may be formed of or comprise crystalline silicon, crystalline germanium, crystalline silicon germanium, or the like. Semiconductor substrate 20 may also be a bulk silicon substrate or a Silicon-On-Insulator (SOI) substrate. Shallow Trench Isolation (STI) regions (not shown) may be formed in semiconductor substrate 20 to isolate the active regions in semiconductor substrate 20. Although not shown, through-vias may be (or may not be) formed to extend into semiconductor substrate 20, and the through-vias are used to electrically inter-couple the features on opposite sides of wafer 2.

In accordance with some embodiments, wafer 2 includes integrated circuit devices 28, which may be formed on the top surface of semiconductor substrate 20. Example integrated circuit devices may include Complementary Metal-Oxide Semiconductor (CMOS) transistors, resistors, capacitors, diodes, and/or the like. The details of the integrated circuit devices are not illustrated herein. In accordance with alternative embodiments, wafer 2 is used for forming interposers, which are free from active devices and passive devices.

Interconnect structure 30 is formed over the integrated circuits, and may include an Inter-Layer Dielectric (ILD, one of dielectric layers 32) formed over semiconductor substrate 20. The ILD fills the space between the gate stacks of transistors (not shown) in the integrated circuit devices. In accordance with some embodiments, the ILD is formed of Phospho Silicate Glass (PSG), Boro Silicate Glass (BSG), Boron-Doped Phospho Silicate Glass (BPSG), Fluorine-Doped Silicate Glass (FSG), silicon oxide, or the like. the ILD may be formed using spin coating, Flowable Chemical Vapor Deposition (FCVD), Chemical Vapor Deposition (CVD), Plasma Enhanced Chemical Vapor Deposition (PECVD), Low Pressure Chemical Vapor Deposition (LPCVD), or the like.

Contact plugs (not shown) are formed in the ILD, and are used to electrically connect the integrated circuit devices to overlying metal lines and vias 34. In accordance with some embodiments, the contact plugs are formed of a conductive material selected from tungsten, aluminum, copper, titanium, tantalum, titanium nitride, tantalum nitride, alloys thereof, and/or multi-layers thereof. The formation of the contact plugs may include forming contact openings in the ILD, filling a conductive material(s) into the contact openings, and performing a planarization process (such as a Chemical Mechanical Polish (CMP) process) to level the top surfaces of the contact plugs with the top surface of the ILD.

Interconnect structure 30 includes dielectric layers 32, which include the ILD and the dielectric layers over the ILD. The dielectric layers 32 over the ILD are alternatively referred to as Inter-Metal Dielectric (IMD) layers 32 hereinafter. In accordance with some embodiments, some lower ones of dielectric layers 32 are formed of a low-k dielectric material having a dielectric constant (k-value) lower than about 3.8, and may be lower than about 3.5 or about 3.0. The IMD hence may be extreme low-k dielectric layers. Dielectric layers 32 may be formed of a carbon-containing low-k dielectric material, Hydrogen SilsesQuioxane (HSQ), MethylSilsesQuioxane (MSQ), or the like.

In accordance with alternative embodiments of the present disclosure, some or all of dielectric layers 32 are formed of non-low-k dielectric materials such as silicon oxide, silicon carbide (SiC), silicon carbo-nitride (SiCN), silicon oxy-carbo-nitride (SiOCN), or the like. Etch stop layers (not shown), which may be formed of silicon carbide, silicon nitride, aluminum oxide, aluminum nitride, or the like, or multi-layers thereof, may be formed between IMD layers 32, and are not shown for simplicity.

Metal lines and vias 34 are formed in dielectric layers 32. The metal lines 34 at a same level are collectively referred to as a metal layer hereinafter. In accordance with some embodiments, interconnect structure 30 includes a plurality of metal layers that are interconnected through vias. Metal lines and vias 34 may be formed through single damascene and/or dual damascene processes. Metal lines and vias 34 may include diffusion barriers and copper-containing metallic materials over the corresponding diffusion barriers. The diffusion barriers may include titanium, titanium nitride, tantalum, tantalum nitride, or the like.

Metal lines 34 include metal lines/pads 34A, which are sometimes referred to as top metal lines/pads. Top metal lines/pads 34A are also collectively referred to as being a top metal layer. The respective dielectric layer 38 may be formed of a non-low-k dielectric material such as Undoped Silicate Glass (USG), silicon oxide, silicon nitride, and/or the like.

In accordance with some embodiments, dielectric layer 40 is formed over the top metal layer. It is appreciated that the illustrated dielectric layers 38, 40, and 42 are examples, and the wafer 2 may include different materials and layers than illustrated. Dielectric layer 40 represents the possible dielectric layer(s) that may be adopted in wafer 2. In accordance with some embodiments, dielectric layer 40 is formed of or comprises an inorganic dielectric material such as silicon oxide, silicon oxynitride, silicon oxy-carbide, silicon oxy carbo-nitride, USG, or the like.

In accordance with some embodiments, dielectric layer 42 is formed as a top surface layer of wafer 2. Dielectric layer 42 may be used for fusion bonding, and hence is alternatively referred to as bond film 42 hereinafter. Bond film 42 may be deposited using Plasma-Enhanced Chemical Vapor Deposition (PECVD), Atomic Layer Deposition (ALD), High Density Plasma Chemical Vapor Deposition (HDPCVD), Plasma Enhanced ALD (PEALD), or the like. Bond film 42 may be formed of or comprise a silicon-containing dielectric material. In accordance with some embodiments, the material of bond film 42 may be formed of or comprise SiON, SiN, SiOCN, SiCN, SiOC, SiC, SiO₂, or the like. Bond film 42 may be formed of a dielectric material different from, or same as, the dielectric material of dielectric layer 40.

As also shown in FIG. 1, vias 44 and bond pads 46 are formed. In accordance with some embodiments, the formation process of vias 44 and bond pads 46 may include two single damascene processes or a dual damascene process. The damascene process(es) may include etching dielectric layers 42 and 40 to form trenches and via openings, and filling the trenches and via openings with a conformal barrier layer and a metallic material. In accordance with some embodiments, the barrier layer comprises Ti, TiN, Ta, TaN or the like. The metallic material may include copper. A planarization process such as a Chemical Mechanical Polish (CMP) process or a mechanical grinding process may then be performed to remove excess portions of the barrier layer and the metallic material. The remaining portions of the barrier layer and the metallic material are vias 44 and bond pads 46. The top surfaces of bond pads 46 are thus coplanar with the top surface of bond film 42.

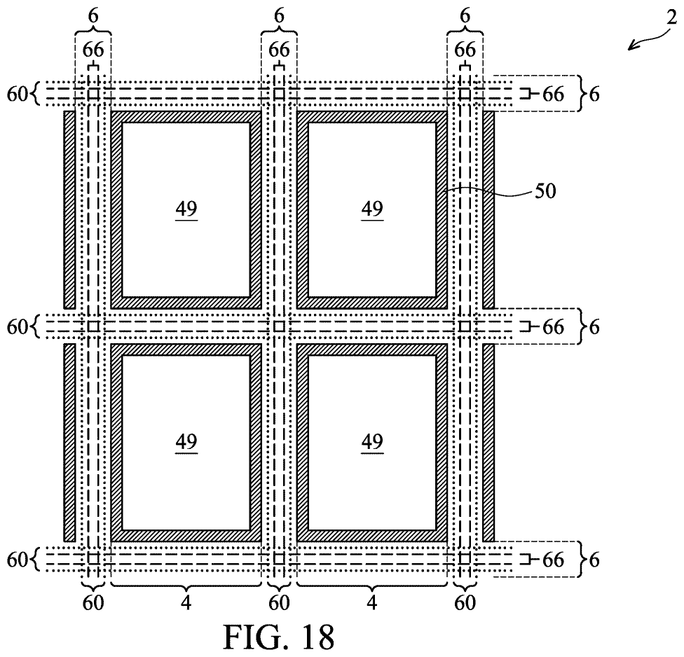

Referring to FIG. 18, which illustrates a top view of wafer 2, a plurality of device dies 4 are arranged as an array including a plurality of rows and columns. A plurality of scribe lines 6 are located between device dies 4. In accordance with some embodiments, seal rings 50 are formed to encircle the active areas 49 of the device dies 4. The active areas 49 are used to form functional integrated circuits (active devices and passive devices) and interconnect structures. Seal rings 50 may be formed as full rings, with no breaks therein in the top view.

Before wafer 2 is singulated, the outer edges of seal rings 50 may be considered as the outer boundaries of the device dies 4. It is appreciated, however, that the subsequent die-saw process will leave some portions of scribe lines 6 outside of the seal rings 50 of the discrete device dies 4. Accordingly, after the singulation process for sawing wafer 2 into discrete device dies 4, the discrete device dies 4 may also include some portions outside of the respective seal rings 50. The discrete device dies 4 generated by sawing wafer 2 are thus larger than the portions inside the outer edges of seal ring 50.

In accordance with some embodiments, each device die 4 may include a single seal ring. Alternatively, each device die 4 may include a plurality of seal rings, with outer seal ring(s) encircling the respective inner seal ring(s)s. When more than one seal ring is formed for each of device dies 4, the illustrated seal ring 50 is the outmost seal ring that is closest to the scribe lines.

Referring to FIG. 1, etching mask 58 is formed on wafer 2 and patterned, and trench 60 is formed in etching mask 58 to expose the underlying wafer 2. The respective process is illustrated as process 202 in the process flow 200 as shown in FIG. 23. The patterned etching mask 58 covers entireties of device dies 4, and further extend directly over (and overlap) some portions of scribe lines 6. Etching mask 58 may comprise a photoresist, and may or may not include an anti-reflective coating. Etching mask 58 may also be a single-layer etching mask, a double-layer etching mask, or a tri-layer etching mask. In accordance with some embodiments, over scribe line 6, there is a single trench 60. In accordance with alternative embodiments, over scribe line 6, there are two trenches 60, with a portion (which is shown as being dashed) of the etching mask 58 being left between the two trenches 60.

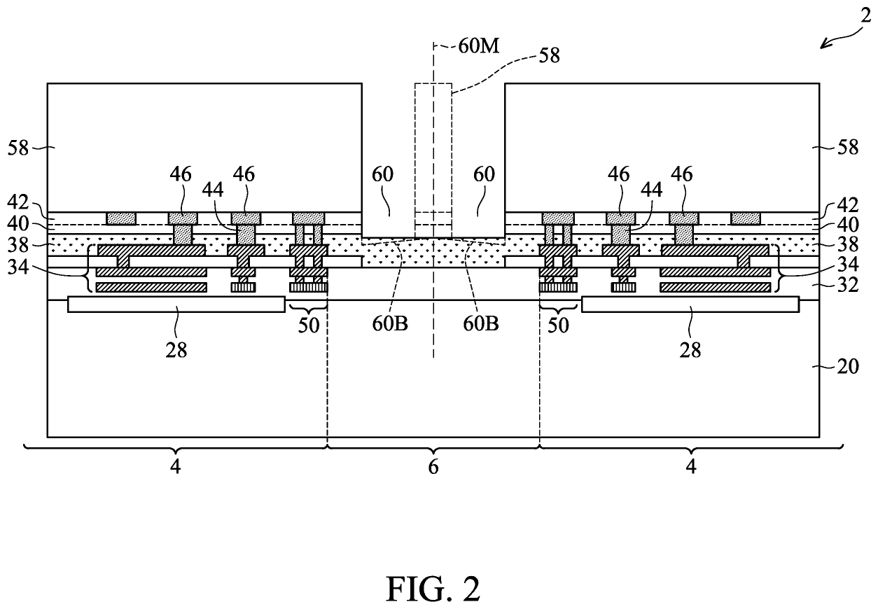

Referring to FIG. 2, an anisotropic etching process is then performed to etch wafer 2, so that trench 60 further extends down into the top portion of wafer 2. Bond film 42 is etched-through. In accordance with some embodiments, trench 60 extends to a same level of the bottom surface of bond film 42 (within process variation). In accordance with some embodiments, the etching includes a dry etching process, which may be a plasma etching process. Depending on the material of bond film 42 and dielectric layer 40, the etching gas may include the mixture of NF₃ and NH₃, the mixture of HF and NH₃, one or more of the gases such as CF₄, NF₃, SF₆, CHF₃, ClF₃, or combinations thereof. Other gases such as O₂, N₂, H₂, NO, and the like, may also be added. Sputtering gas such as argon may be added, so that some sputtering effect may be used to enhance the anisotropic effect.

In the etching process, dielectric layer 40 may be used as an etch stop layer in accordance with some embodiments when dielectric layer 40 is formed of a dielectric material that is different from the dielectric material of bond film 42. In accordance with some embodiments in which bond film 42 is formed of a same dielectric material as dielectric layer 40, or bond film 42 and dielectric layer 40 comprise different dielectric materials, but the difference is not adequate to result in enough etching selectivity, the etching may also be performed using a time mode to stop the etching.

The bottom of trench 60 may be higher than the top surface of substrate 20. Accordingly, a dielectric layer(s), which may be a remaining portion of dielectric layer 40, may be left over underlying trench 60. In accordance with some embodiments, the bottom of trench is flat as shown in FIG. 2. In accordance with alternative embodiments, process conditions of the plasma etching process is adjusted, so that the middle portion of the bottom of trench 60 is higher than the edge portions, which bottom surface is represented by dashed line marked as 60B. The profile of the bottom 60B may be achieved by utilizing charging effect due to the accumulation of charges from plasma, for example, by adjusting the height of etching mask 58 to a proper value.

Also, as shown in FIG. 2, there may be a single trench 60 in each scribe line 6. Trench 60 may cross the middle line 60M of the scribe line 6, which middle line is in the middle of scribe line 6 and has equal distances to the seal rings 50 in opposing device dies 4. In accordance with alternative embodiments, there are two trenches 60 extending into wafer 2, with an unetched portion (illustrated as being dashed) of dielectric layer(s) 40/42 being left between two trenches 60.

Referring to the top view of wafer 2 as shown in FIG. 18, a plurality of trenches 60 are formed and interconnected as a grid. Scribe lines 6 are also interconnected as a grid, and the grid of trenches 60 are inside the grid of scribe lines 6, with the edges of trenches 60 being spaced apart from the boundaries of scribe lines 6.

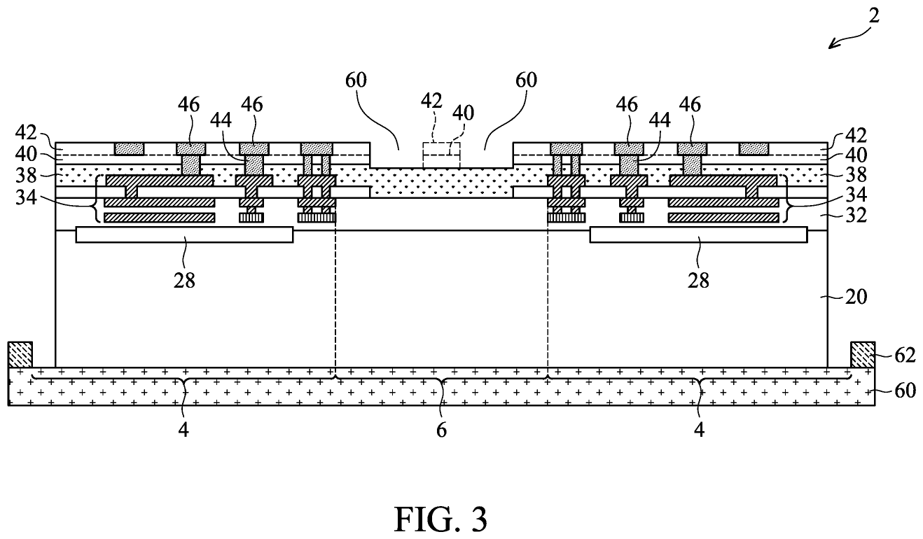

After the etching process, the etching mask 58 as shown in FIG. 2 is removed. Next, the front side of wafer 2 may be attached to a back-grinding tape (not shown). A backside grinding process may then be performed, so that the substrate 20 of wafer 2 is thinned. After the backside grinding process, wafer 2 is detached from the back-grinding tape. Next, as shown in FIG. 3, the backside of wafer 2 is attached to dicing tape 60, which is fixed on frame 62.

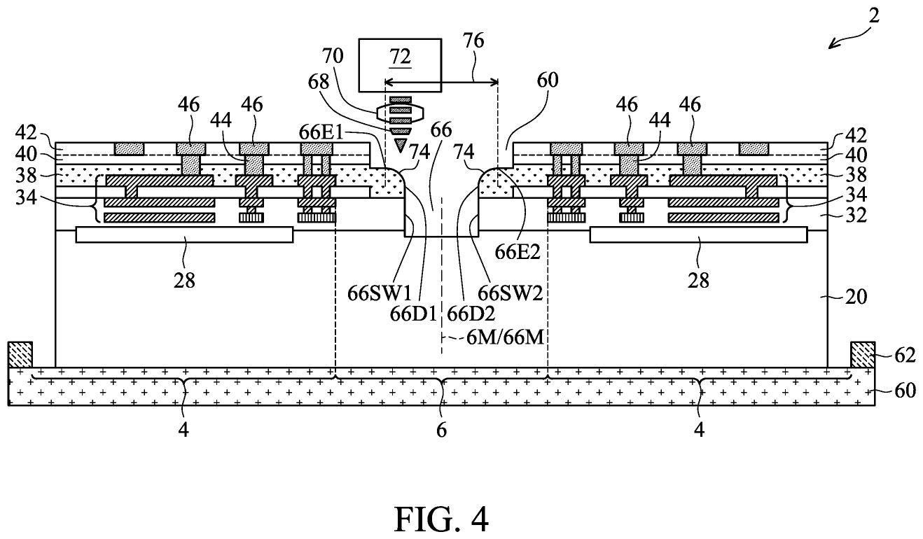

Subsequently, as shown in FIG. 4, a laser grooving process is performed using a laser beam 68, so that trench 66 is formed to extend from the bottom of trench 60 downwardly. The respective process is illustrated as process 204 in the process flow 200 as shown in FIG. 23.

In accordance with some embodiments, the laser grooving process is performed until the bottom of trench 66 at least reaches, or may extend into semiconductor substrate 20. During the laser grooving process, the dielectric materials and dummy conductive features (not show) on the path of trench 66 are removed. In accordance with some embodiments, trench 66 is in the middle of trench 60, with the opposing edges of trench 66 having equal distances from the nearest opposite edges of the trench 60.

In accordance with some embodiments, as shown in FIG. 18, a plurality of trenches 66 are formed in wafer 2, each in one of scribe lines 6 and in a corresponding trench 60. In the top view of wafer 2, the trenches 66 are also interconnected as a grid. In the top view, trenches 66 are inside, and are narrower than, the corresponding trenches 60. The edges of trenches 66 are spaced apart from the edges of trenches 60, as can also be realized from FIG. 3 and FIG. 18.

In accordance with some embodiments, the laser grooving process is performed by projecting laser pulses on wafer 2. The laser pulses have a low power per pulse, so that more pulses are adopted, and the surface of the projected portions of resulting wafer 2 is smoother. For example, the laser grooving process may be performed through picosecond laser pulses. FIG. 4 illustrates an example laser beam generator and projector 72, which generates laser beam 68 and projects laser beam 68 on wafer 2. Lens 70 is also used to focus laser beam 68 and to generate a small laser beam spot.

In accordance with some embodiments, wafer 2 has continuously deepened trench 66, wherein from the regions farther away from the middle line 6M of scribe line 6 to the respective regions closer to an abruptly deepened portion of trench 66, the depth of trench 66 gradually and continuously increase. The middle line 6M of scribe line 6 may also be the middle line 66M of trench 66. The abruptly deepened portion of trench 66 have abrupt sidewalls 66SW1 and SW2 (collectively referred to as sidewalls 66SW) formed, which sidewalls 66SW may be vertical or may be slightly slanted, as will be discussed in more detail in subsequent paragraphs.

In accordance with some embodiments, in the laser grooving process, the laser beam 68 is projected to the part of scribe line 6 between end points (positions) 66E1 and 66E2, and the parts of scribe line 6 outside of the part between end points 66E1 and 66E2 are not grooved. Points 66D1 and 66D2 mark where the sidewalls 66SW1 and 66SW2 are to be generated.

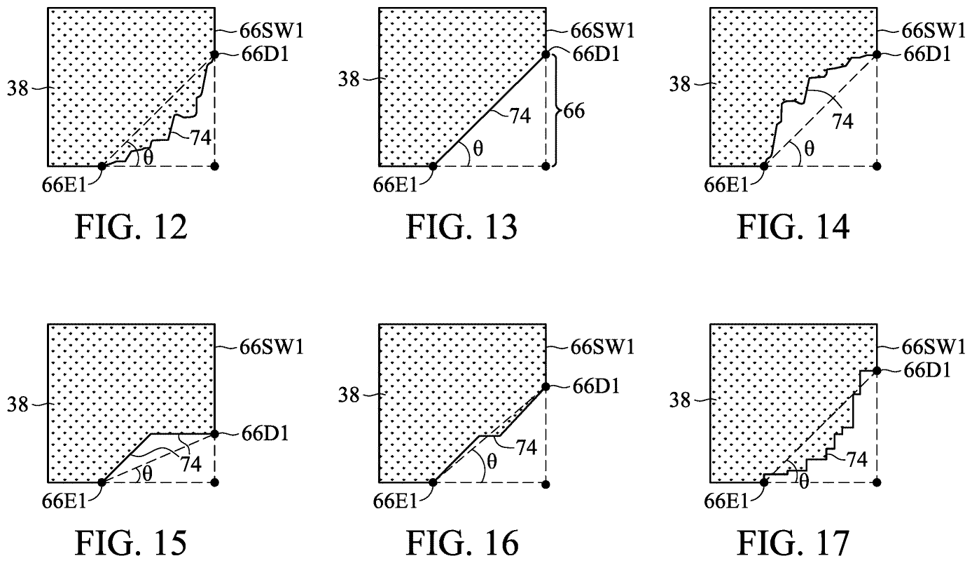

Surfaces 74 are formed between end point 66E1 and sidewall 66SW1, and between end point 66E2 and sidewall 66SW2. In an embodiment, from the end point 66E1 to point D1, and from end point 66E2 to point D2, the depths (measured from the height of end point 66E1) of trench 66 are gradually and continuously (with small roughness due to process variations) increased. Points (positions) 66D1 and 66D2 are the points where the depth of trench 66 increase abruptly. In accordance with some embodiments, surfaces 74 are curved. In accordance with alternative embodiments, surfaces 74 are straight. The profiles of surfaces 74 are discussed in detail referring to FIGS. 12-17.

In accordance with some embodiments, laser generator and projector 72 generates and projects a plurality of laser pulses to burn wafer 2. Each of the laser pulses removes a portion of the materials receiving the laser pulse. In accordance with some embodiments, the laser pulses have the same energy. In accordance with alternative embodiments, the laser pulses have different energies. For example, end points 66E1 and 66E2 may be formed through laser pulses having lower energies than the portions of trench 66 between sidewalls 66SW1 and 66SW2, so that the desirable profile may be formed, while the efficiency of the laser grooving process is not sacrificed.

To form surfaces 74 with small roughness and having desirable profiles, the power carried by each laser pulse is small. This may be achieved by reducing the length of the individual pulses. For example, picosecond laser pulses may be adopted, wherein each laser pulse may have a duration in the range between about 1 picosecond and about 100 picoseconds. The power carried by each pulse may be determined based on the desirable small roughness as discussed. For example, experiments may be performed on a plurality of samples having the same structure using different power levels. Higher power will result in higher roughness and vice versa. The roughness of plurality of samples are measured. The power that is small enough to achieve the desirable roughness, but is not too small to unnecessarily reduce the throughput is used.

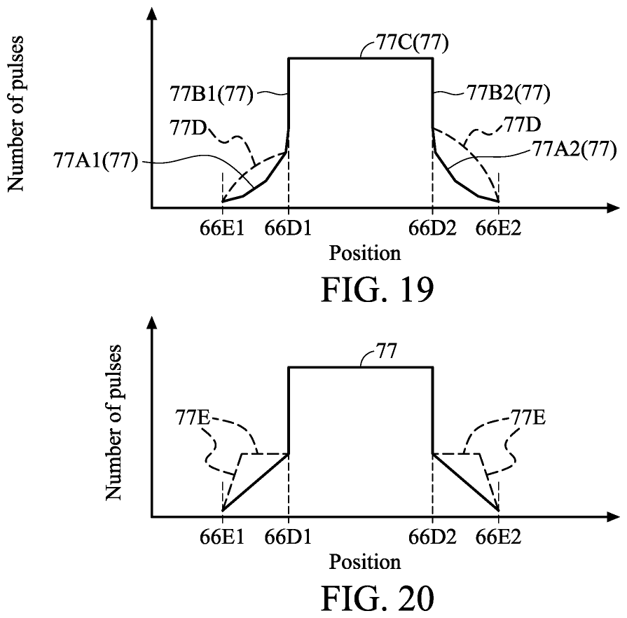

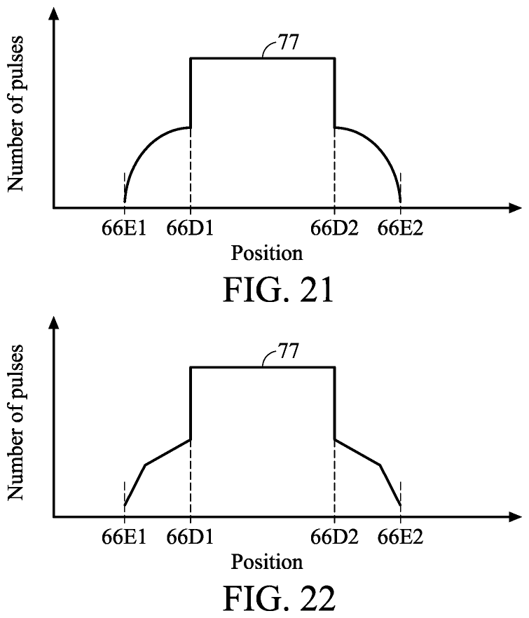

The gradually changed surfaces 74 are achieved by adjusting the power of the laser pulses used for burning different parts of wafer 2. The deeper portions of trench 66 may be formed through more laser pulses, and vice versa. FIG. 19 illustrates line 77, which represents the count of laser pulses projected to individual points between end points 66E1 and 66E2 (marked in FIG. 19, also refer to FIG. 4) as a function of the position of the points in accordance with some embodiments. The X-axis represents the positions in arrow 76 in FIG. 4, and the Y-axis represents the number of laser pulses projected to each position.

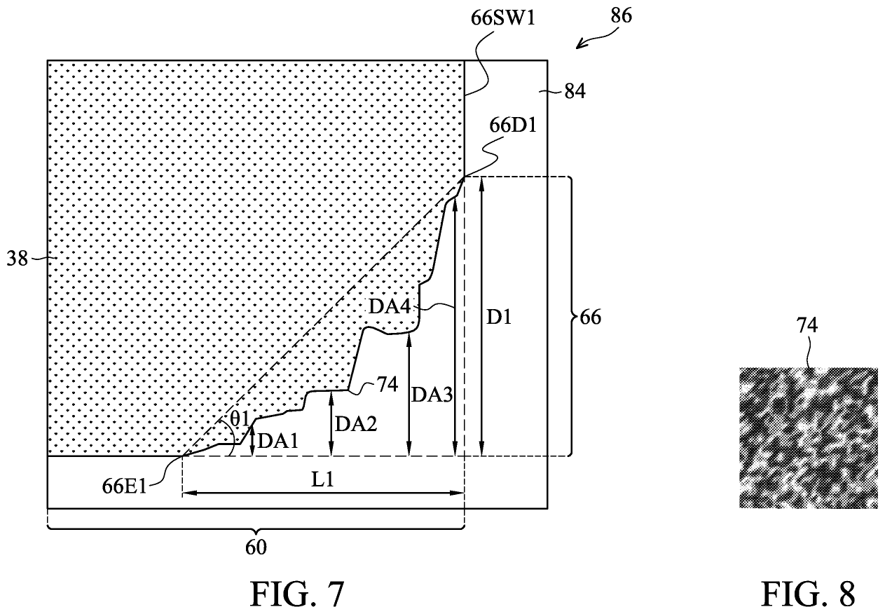

In accordance with some embodiments, points 66E1 and 66E2 receive smallest number of laser pulses, and the number of laser pulses gradually increase when the burned portions are at positions closer to points 66D1 and 66D2. The deep portion between points 66D1 and 66D2 may receive an abruptly increased number of laser pulses, as represented by portions 77B1, 77B2, and 77C in FIG. 19. Furthermore, the slope of the portions 77A1 and 77A2 may gradually increase. Alternatively stated, the numbers of pulses increase exponentially from position 66E1 to position 66D1 in accordance with some embodiments. The resulting profile of surface 74 may be similar to what are shown in FIGS. 7, 12 and 17 in accordance with some embodiments.

FIG. 20 illustrates the count of laser pulses as a function of position in accordance with alternative embodiments. The slope of the line stays the same from position 66E1 to position 66D1. Alternatively stated, the numbers of pulses increase linearly from position 66E1 to position 66D1. At point 66D1, an abruptly greater number of laser pulses is adopted to form the deepened potion of trench 66.

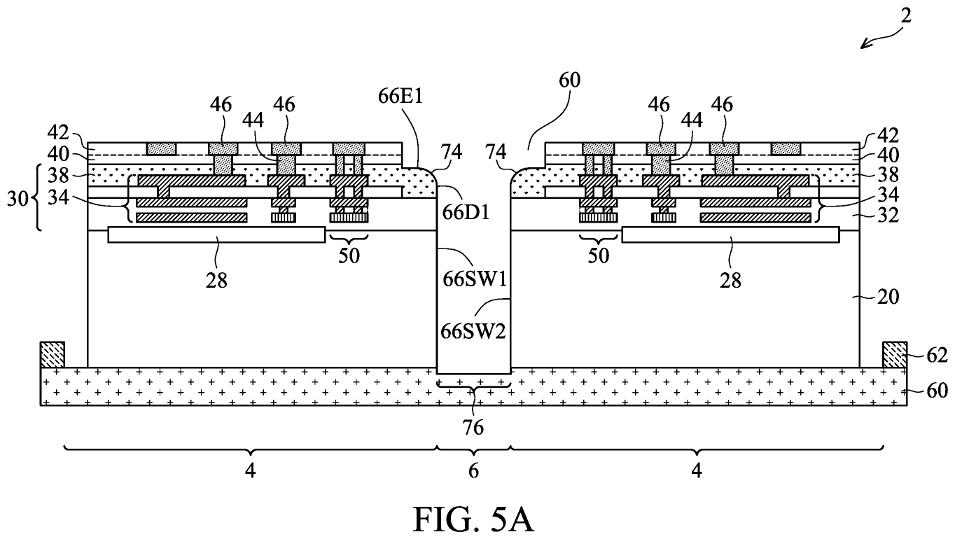

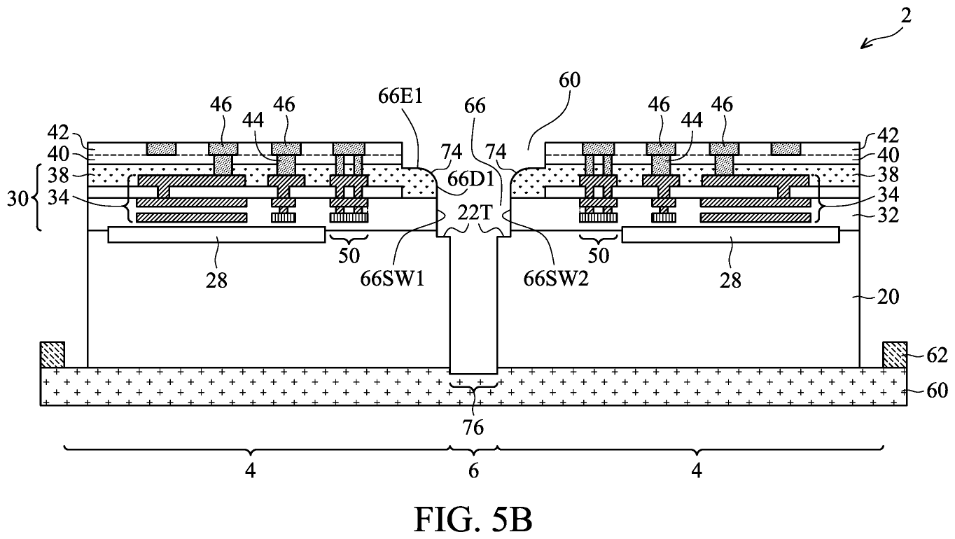

Referring to FIG. 5A or 5B, wafer 2 is sawed (singulated) in a die-saw process. The respective process is illustrated as process 206 in the process flow 200 as shown in FIG. 23. The die-saw process may be performed using a blade. Cutting line 76 is thus formed. A plurality of cutting lines 76 are formed, each extending down from one of trenches 66 as shown in FIG. 18. Wafer 2 is thus cut into a plurality of discrete device dies 4, which may be identical to each other. In accordance with some embodiments, as shown in FIG. 5A, the outer boundaries of cutting line 76 are aligned to the sidewalls 66SW1 and/or 66SW2. Accordingly, one or both of the gradually changed surfaces 74 extends to the top ends of the corresponding sidewalls 66SW1 and/or 66SW2, which sidewalls 66SW1 and/or 66SW2 further form the sidewalls of the resulting device dies 4.

In accordance with alternative embodiments, as shown in FIG. 5B, cutting line 76 is narrower than, and may be in the middle of, the respective trench 66, which means that cutting line 76 has equal distances (widths) from the nearest edges of trench 66. Accordingly, the gradually changed surfaces 74 extend to the top ends of the corresponding sidewalls 66SW1 and/or 66SW2, which sidewalls are further ended at the bottom of trench 66. A top surface 22T of semiconductor substrate 22 thus may form the bottom of trench 66, and the top surface 22T of semiconductor substrate 22 extends laterally to the edge of the resulting device die 4.

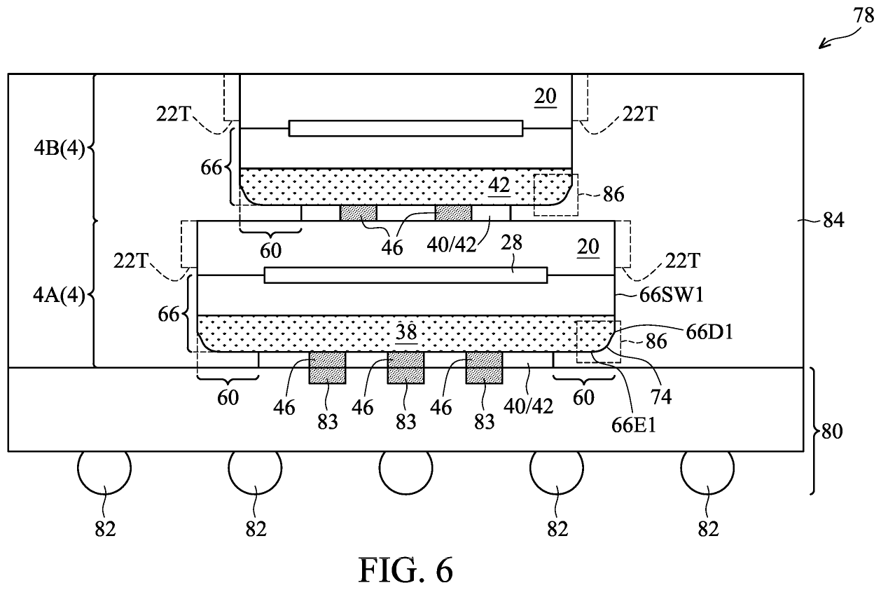

FIG. 6 illustrates the packaging of device dies 4 (including device dies 4A and 4B) in accordance with some embodiments, in which device dies 4A and 4B are packaged to form package 78. The respective process is illustrated as process 208 in the process flow 200 as shown in FIG. 23. Each of the device dies 4A and 4B may have the structure as discussed above, and may be formed through the same processes as shown in FIGS. 1-4 and 5A (or 5B). In accordance with some embodiments, device die 4A is bonded to package component 80 through bond pads 83. Package component 80 may include a device die, a package including device die(s) packaged therein, an interposer, a package substrate, a printed circuit board, a blank silicon carrier, or the like. Electrical connectors 82 may be formed and connected to device die 4A in accordance with some embodiments. Device die 4B is bonded to device die 4A. While not shown, device die 4A may include through-silicon vias (TSVs) therein to electrically connect device die 4B to package component 80. Dashed lines (with the bottom surface marked as 22T) are also shown to represent that the device dies 4A and 4B have the structures shown in FIG. 5B.

An encapsulant 84, which may be a molding compound, a molding underfill, or the like, is used to encapsulate device dies 4A and 4B. Molding compound 84 may include a base material and filler particles in the filler materials. The base material may include polymer, resin, epoxy, and/or the like. The filler particle may be the spherical particles of silica, aluminum oxide, or the like. The encapsulation process may include dispensing the molding compound in a flowable form, and then curing the molding compound as a solid. The encapsulant 84 may flow into trenches 60 and 66 (if exists in device die(s) 4A and/or 4B) through capillary. An advantageous feature of the present disclosure is that by forming gradually changed surfaces 74 having small roughness, it is easy for the molding compound to flow into trenches 60, and thus no void is formed, or the void is reduced, if formed.

FIGS. 7 and 9-17 illustrate the schematic amplified views of the surfaces 74 of the corner portions of device dies 4 in accordance with some embodiments. The illustrated amplified views may be obtained from the regions 86 in FIG. 6. End point 66E1 and point 66D1 (FIGS. 4, 19, and 20) and sidewall 66SW1 are also illustrated.

Referring to FIG. 7, the corner portion of the device die having surface 74 may also be referred to as the eave portion of device die 4. From point 66E1 to point 66D1, the depths of trench 66 are gradually increased, for example, with depth DA1 <DA2<DA3<DA4. Surface 74 is thus referred to as a gradually changed surface 74. With the depths of surface 74 being gradually increased, it is easier for molding compound 84 to flow into trench 60, which is also the gap between package component 80 (FIG. 6) and device die 4A, or the gap between device dies 4A and 4B. The lateral length L1 (FIG. 7) of the corner portion cannot be too big or too small. If the lateral length L1 is too small, the edge portion is too steep, the corner is too sharp, and it is difficult for the encapsulant 84 (FIG. 6) to flow into trench 60. Void may be formed in trench 60. If the lateral length L1 is too big, capillary effect is small, and void may also be formed in trench 60. In accordance with some embodiments, the lateral length L1 may be equal to or greater than about 2 μm, and may be in the range between about 2 μm and about 4 μm.

The vertical length D1 of the corner portion cannot be too big or too small. If the vertical length D1 is too small, the corner is too sharp, and it is difficult for the encapsulant 84 (FIG. 6) to flow into trench 60. Void may be formed in trench 60. If the vertical length D1 is too big, it is difficult for capillary effect to occur since the gap is too high. Void may also be formed in trench 60. In accordance with some embodiments, the vertical length D1 may be equal to or greater than about 2 μm, and may be in the range between about 2 μm and about 4 μm. Furthermore, to ensure the corner surface 74 is balanced, lateral length L1 and vertical length D1 may be equal to or close to each other, for example, with a difference smaller than about 20 percent of lateral length L1, and smaller than about 20 percent of vertical length D1.

Referring to FIG. 7, the gradually changed surface 74 is shown as having a roughness schematically. Since the encapsulant 84 has fillers therein, if the roughness is high, more resistance is provided by the roughness for the flow and the capillary of molding compound 84. It is thus more difficult for the encapsulant 84 to flow into trench 60, resulting in the formation of voids in trench 60, and possibly cracks in the resulting package. In accordance with embodiments, the roughness of surface 74 is smaller than about 1.5 μm, smaller than about 0.5 μm, smaller than about 0.2 μm, or smaller than about 0.1 μm. The roughness may be the root mean square roughness Rq in accordance with some embodiments. The reduction of the roughness is achieved by reducing the power of laser pulses, the reduction of the duration of each of laser pulses, the increase in the number of laser pulses (so that each laser pulse results in a smaller indent), and the overlapping of laser pulse spots.

In accordance with some embodiments, points 66E1 and 66D1 have a connection line forming tilt angle θ1 with a horizontal line. It is appreciated that if the tilt angle θ1 is too high or too small, vertical length L1 and vertical length D1 will be too big or too small correspondingly. It is thus more difficult for the encapsulant 84 to flow into trench 60, resulting in the formation of voids in trench 60, and possibly cracks in the resulting package. In accordance with embodiments, tilt angle θ1 is in the range between about 20 degrees and about 60 degrees.

FIG. 8 graphically illustrates the surface 74, wherein different portions with different gray levels represent higher and lower portions of surface 74.

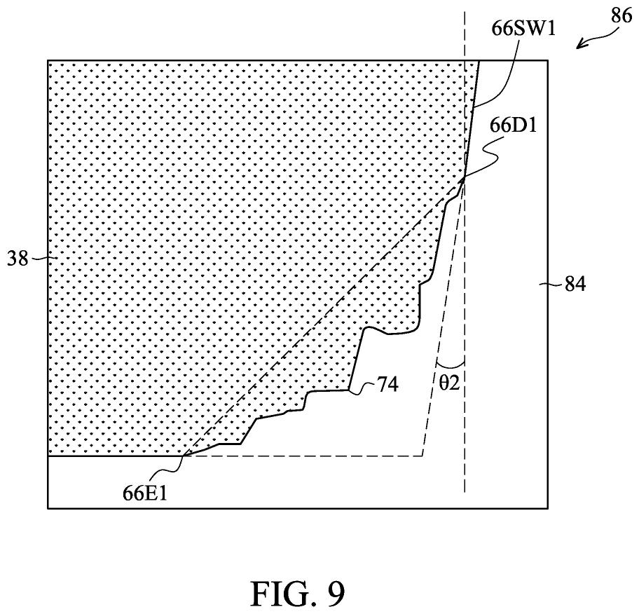

FIG. 9 illustrates an embodiment in which sidewall 66SW1 is not vertical. Rather, sidewall 66SW1 is slightly tilted. This may be achieved by, for example, by making the portions 77B1 in FIG. 19 to have a high slope, but not vertical. In accordance with some embodiments, sidewall 66SW1 form tilt angle θ2 with a vertical line. It is appreciated that if the tilt angle θ2 in FIG. 9 is too high, a significant gap is formed under the slanted sidewall 66SW1. The gap is too high, making the capillary of encapsulant 84 difficult to occur, resulting in the formation of voids in trench 60, and possibly cracks in the resulting package. In accordance with embodiments, tilt angle θ2 is smaller than about 20 degrees.

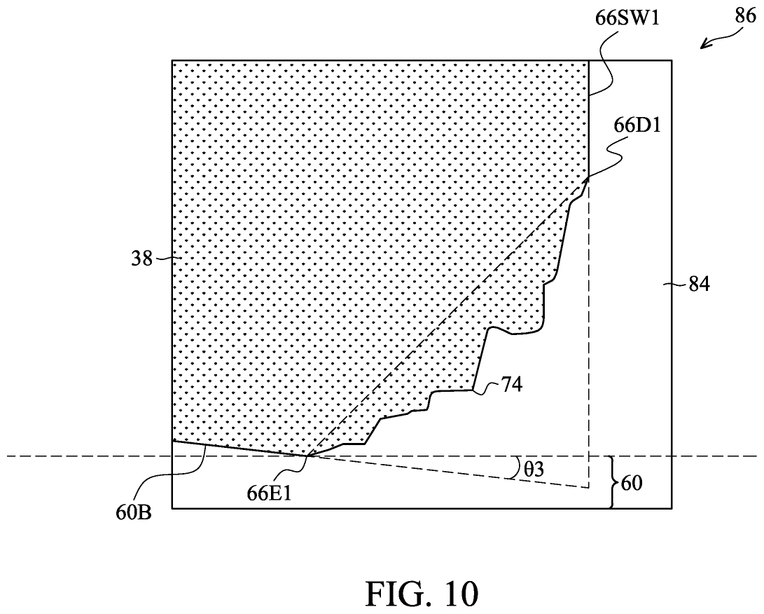

FIG. 10 illustrates an embodiment wherein bottom surface 60B (refer to the dashed surface 60B in FIG. 2) is not horizontal. In accordance with some embodiments, bottom surface 60B has outer portions (the portions on the right side, also refer to FIG. 6) lower than the inner portion (the portions on the left side). This causes the outer portion of trench 60 (FIG. 6) to have smaller heights than the respective inner portions. This is similar to the embodiment in which the bottom surface 60B is horizontal, and the smaller entrance of trench 60 may help the capillary effect. It is thus less likely for void to occur in trench 60. It is appreciated that if the tilt angle θ3 of bottom surface 60B is too big, it is difficult for the molding compound to pass the entrance of trench 60. In accordance with embodiments, tilt angle θ3 is smaller than about 20 degrees.

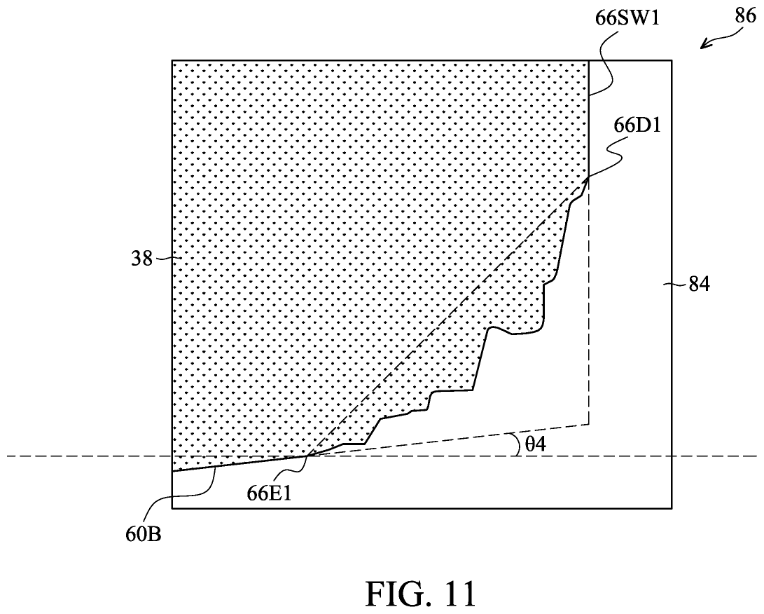

In accordance with alternative embodiments, as shown in FIG. 11, the bottom surface 60B has outer portions higher than the respective inner portions. It is appreciated that if tilt angle θ4 is too big, the entrance of trench 60 is too wide, and may cause capillary difficult to occur. In accordance with embodiments, tilt angle θ4 is smaller than about 20 degrees.

FIGS. 12 through 17 illustrate some profiles of surfaces 74 in accordance with some embodiments. FIG. 12 is similar to the embodiments shown in FIG. 7, in which surface 74 is convex, curved and rounded. This embodiment may be formed by the laser pulse profile as shown in FIG. 19.

FIG. 13 illustrates an embodiment in which surface 74 is straight, and trench 66 has a triangular shape. This embodiment may be formed by the laser pulse profile as shown in FIG. 20.

FIG. 14 illustrates an embodiment in which the sidewall view of surface 74 has a concave and curved shape. This embodiment may be formed by the laser pulse profile 77D as shown in FIG. 19.

FIG. 15 illustrates an embodiment in which the sidewall view of surface 74 has concave and straight edges. This embodiment may be formed by the laser pulse profile 77E as shown in FIG. 20.

FIG. 16 illustrates another profile with the portions of surface 74 being substantially aligned to a straight line, with small offsets.

FIG. 17 illustrates another profile having convex and curved surface 74, with process variation causing unexpected dents.

The embodiments of the present disclosure have some advantageous features. By making the corner portions of device dies gradually changed through laser pulses that have low power, the encapsulating process is easier. By reducing the duration of the laser pulses, such as using picosecond laser pulses, more laser pulses are adopted, with each of the laser pulses causing smaller indents on wafers. This results the surface roughness of the surface generated by laser grooving to be smoother.

In accordance with some embodiments of the present disclosure, a method comprises forming a wafer; etching a first dielectric layer of the wafer to form a first trench between two dies of the wafer, wherein a first portion of a second dielectric layer of the wafer is directly underlying the first trench; and performing a laser grooving process to remove the first portion of the second dielectric layer of the wafer, wherein a second trench is formed, and is underlying and joined to the first trench, wherein the second dielectric layer comprises a corner region where the first trench is joined to the second trench, wherein portions of a top surface of the corner region closer to a center middle line of the second trench are increasing lower than respective portions of the top surface of the corner region farther away from the center middle line.

In an embodiment, the laser grooving process is performed using picosecond laser beams. In an embodiment, the top surface has a roughness smaller than about 1.5 μm. In an embodiment, in the laser grooving process, more laser pulses are projected onto portions of the second dielectric layer closer to the center middle line than portions of the second dielectric layer farther away from the center middle line. In an embodiment, in the laser grooving process, laser pulses are projected on a region between a first point farther away from the center middle line and a second point closer to the center middle line, and wherein from the first point to the second point, numbers of laser pulses increase gradually.

In an embodiment, from the first point to the second point, the numbers of laser pulses increase linearly. In an embodiment, from the first point to the second point, the numbers of laser pulses increase exponentially. In an embodiment, the method further comprises sawing the wafer through the second trench, wherein the wafer is separated into a plurality of dies. In an embodiment, the method further comprises bonding a die in the plurality of dies to a package component; and molding the die in a molding compound, wherein the molding compound is filled into the first trench.

In accordance with some embodiments of the present disclosure, a method includes forming a wafer, etching a first dielectric layer of the wafer to form a first trench between two dies of the wafer, wherein a first portion of a second dielectric layer of the wafer is directly underlying the first trench; and performing a laser grooving process to remove the first portion of the second dielectric layer and to form a second trench, wherein the laser grooving process is performed using picosecond laser beams. In an embodiment, a surface of the wafer formed by the laser grooving process is rounded. In an embodiment, the method further comprises sawing the wafer through the second trench, wherein the wafer is separated into a plurality of dies.

In accordance with some embodiments of the present disclosure, a structure comprises a device die comprising a semiconductor substrate comprising a first edge; a first dielectric layer underlying the semiconductor substrate, wherein the first dielectric layer comprises a bottom surface; and a corner surface connecting the bottom surface to the first edge, wherein portions of the corner surface closer to the first edge are increasingly higher than respective portions of the corner surface closer to the bottom surface; and a second dielectric layer underlying and contacting the first dielectric layer, wherein the second dielectric layer comprises a second edge laterally recessed from the first edge.

In an embodiment, the corner surface is rounded. In an embodiment, the corner surface is straight. In an embodiment, the corner surface has a roughness smaller than about 1.5 μm. In an embodiment, the corner surface has a lateral length and a vertical length having a difference smaller than about 20 percent of both of the lateral length and the vertical length. In an embodiment, an outer portion of the bottom surface extends laterally beyond the second edge, and the outer portion of the bottom surface is tilted with portions farther away from the second edge being lower than respective portions of the bottom surface closer to the second edge.

In an embodiment, the outer portion of the bottom surface has a tilt angle smaller than about 20 percent. In an embodiment, the structure further comprises a package component underlying and joined to the second dielectric layer; and a molding compound comprising a first part encircling the device die; and a second part overlapped by the device die and forming an interface with the bottom surface of the first dielectric layer.

In accordance with some embodiments of the present disclosure, a structure comprises a package component; a device die over and joined to the package component; and an encapsulant, wherein the device die is in the encapsulant, and wherein the encapsulant contacts the device die to form an edge interface formed between the encapsulant and an edge of the device die; a first bottom surface formed between the encapsulant and a bottom of the device die; and a corner interface joining the edge interface to the first bottom interface, wherein the corner interface is rounded and continuous.

In an embodiment, the corner interface has a roughness smaller than about 1.5 μm. In an embodiment, the device die further comprises a second bottom surface in physical contact with the package component, and the second bottom surface is lower than the first bottom surface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a wafer;
etching a first dielectric layer of the wafer to form a first trench between two dies of the wafer, wherein a middle portion of a second dielectric layer of the wafer is directly underlying the first trench;
performing a laser grooving process to remove the middle portion of the second dielectric layer of the wafer, wherein a second trench is formed in the second dielectric layer, and is underlying and joined to the first trench, wherein the laser grooving process results in the second dielectric layer to comprise a top surface, a sidewall, and a corner surface facing the second trench, and wherein the corner surface connects the top surface to the sidewall; and
sawing the wafer to separate the two dies of the wafer from each other.

2. The method of claim 1, wherein the laser grooving process is performed using picosecond laser beams.

3. The method of claim 1, wherein in the laser grooving process, portions of the second dielectric layer closer to the sidewall receive greater numbers of laser pulses than portions of the second dielectric layer farther away from the second trench.

4. The method of claim 1, wherein in the laser grooving process, more laser pulses are projected onto portions of the second dielectric layer closer to a center middle line than portions of the second dielectric layer farther away from the center middle line, wherein the center middle line is in the middle of the two dies.

5. The method of claim 4, wherein in the laser grooving process, laser pulses are projected on a region between a first point farther away from the center middle line and a second point closer to the center middle line, and wherein from the first point to the second point, numbers of laser pulses increase gradually.

6. The method of claim 5, wherein from the first point to the second point, the numbers of laser pulses increase linearly.

7. The method of claim 5, wherein from the first point to the second point, the numbers of laser pulses increase exponentially.

8. The method of claim 1, wherein the corner surface is continuously curved in a direction pointing from the top surface to the sidewall.

9. The method of claim 1 further comprising:
bonding a die of the two dies to a package component; and
molding the die in a molding compound, wherein the molding compound is filled into the first trench.

10. A method comprising:
forming a wafer;
etching a first dielectric layer of the wafer to form a first trench between two dies of the wafer, wherein a middle portion of a second dielectric layer of the wafer is directly underlying the first trench, and wherein a center middle line is in the middle of the two dies; and
performing a laser grooving process to remove the middle portion of the second dielectric layer and to form a second trench, wherein the laser grooving process is performed using picosecond laser beams, and wherein in the laser grooving process, laser pulses are projected on a region between a first point farther away from the center middle line and a second point closer to the center middle line, and wherein from the first point to the second point, numbers of laser pulses increase gradually.

11. The method of claim 10, wherein a corner of the second dielectric layer by the laser grooving process is rounded.

12. The method of claim 10 further comprising sawing the wafer through the second trench, wherein the two dies of the wafer are separated from each other.

13. A method comprising:
forming a wafer;
grooving the wafer; and
sawing the wafer to separate a device die in the wafer from other dies in the wafer, wherein the device die comprises:
a semiconductor substrate comprising a first edge;
a first dielectric layer over the semiconductor substrate, wherein the first dielectric layer comprises:
a top surface;
a second edge; and
a corner surface connecting the top surface to the second edge, wherein portions of the corner surface closer to the second edge are increasingly lower than respective portions of the corner surface closer to the top surface; and
a second dielectric layer over and contacting the first dielectric layer.

14. The method of claim 13, wherein the grooving the wafer comprises using a laser beam to round the corner surface.

15. The method of claim 13, wherein the grooving the wafer comprises using a laser beam to shape the corner surface as being straight and slanted.

16. The method of claim 13, wherein the corner surface has a roughness smaller than about 1.5 μm.

17. The method of claim 13, wherein the corner surface has a lateral length and a vertical length having a difference smaller than about 20 percent of both of the lateral length and the vertical length.

18. The method of claim 13, wherein the first dielectric layer extends laterally beyond the second dielectric layer.

19. The method of claim 18, wherein the top surface of the first dielectric layer is planar, and is joined to an additional edge of the second dielectric layer.

20. The method of claim 13 further comprising:
bonding a package component to the device die; and
applying a molding compound comprising:
a first part encircling the device die; and
a second part overlapping the device die and forming an interface with the top surface of the first dielectric layer.
